(19) United States
(12) Patent Application Publication
(10) Pub. No.: US 2020/0198300 A1
(43) Pub. Date: Jun. 25, 2020

(54) FLEXIBLE GLASS MEMBRANE,METHOD FOR MANUFACTURING THE SAME,AND ELECTRONIC DEVICE COMPRISING THE SAME

(71) Applicant: AAC Technologies Pte. Ltd., Singapore city (SG)

(72) Inventors: Wei Liu, Shenzhen (CN); Taiming Jiang, Shenzhen (CN); Ji Chen, Shenzhen (CN)

(21) Appl. No.: 16/706,877

(22) Filed: Dec. 9, 2019

(30) Foreign Application Priority Data
Dec. 25, 2018 (CN) 201811588238.5

(51) Int. Cl. B32B 17/06; B32B 27/40; B32B 7/12; B32B 37/12; B32B 37/18; B32B 38/00; C09J 7/35; C09J 7/25; C09J 5/06; H05K 5/03

(52) U.S. Cl. CPC B32B 17/064; C09J 2205/31; B32B 7/12; B32B 37/1207; B32B 37/182; B32B 38/0008; B32B 38/145; C09J 7/35; C09J 7/25; C09J 5/06; H05K 5/03; B32B 2255/10; B32B 2255/28; B32B 2305/72; B32B 2307/546; B32B 2307/4023; B32B 2037/1223; B32B 2310/0831; B32B 2375/00; C09J 2475/006; B32B 27/40

(57) ABSTRACT

A flexible glass membrane, a method for manufacturing the flexible glass membrane, and an electronic device including the flexible glass membrane are disclosed. The flexible glass membrane includes a hot-melt adhesive layer, a thermoplastic polyurethane film layer, a base coating layer, a drawing-transferring layer, an optical coating layer, and an ink layer. The hot-melt adhesive layer, the thermoplastic polyurethane film layer, the base coating layer, the drawing-transferring layer, the optical coating layer, and the ink layer may be successively stacked on one another.

### TECHNICAL FIELD

The present disclosure relates to the technical field of accessories of electronic products, and in particular, to a flexible glass membrane, a method for manufacturing the flexible glass membrane, and an electronic device comprising the flexible glass membrane.

### BACKGROUND

With development of technology and immediate needs of people for office and entertainment, handheld electronic devices (such as tablet computers, mobile phones, and the like) are increasingly popular with people. The electronic device industry is changing with each passing day. Glass covers of the electronic devices have been developed from flat glass covers to 2.5 dimensional (2.5D) covers, and now the glass covers have been further developed from the 2.5D covers to three-dimensional (3D) covers. Besides, the 3D covers have been developed from the covers having curved surfaces at two sides/edges to the covers having curved surfaces along peripheries of the covers. Compared with plastic covers, the glass covers have good touch and beautiful colors. However, safety problems such as fragility and the like exist in the glass covers.

### BRIEF DESCRIPTION OF THE DRAWINGS

FIG. 1 is a cross-sectional view of a flexible glass membrane according to some embodiments of the present disclosure.

FIG. 2 is a flow chart of a method for manufacturing the flexible glass membrane according to some embodiments of the present disclosure.

FIG. 3 is a schematic view showing a state after the block S1 of the method shown in FIG. 2 has been executed.

FIG. 4 is a schematic view showing a state after the block S2 of the method shown in FIG. 2 has been executed.

FIG. 5 is a schematic view showing a state after the block S3 of the method shown in FIG. 2 has been executed.

FIG. 6 is a schematic view showing a state after the block S4 of the method shown in FIG. 2 has been executed.

### DETAILED DESCRIPTION

The technical solutions in the embodiments of the present disclosure will be clearly and completely described in detail below with reference to the accompanying drawings in the embodiments of the present disclosure. Apparently, the embodiments described herein are only some exemplary embodiments, not all the embodiments. Based on the embodiments described in the present disclosure, one skilled in the art may acquire all other embodiments without any creative efforts. All these shall be covered within the protection scope of the present disclosure.

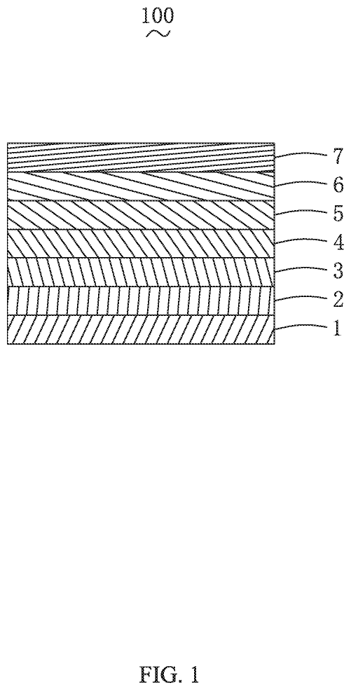

As shown in FIG. 1, a flexible glass membrane 100 may be provided in some embodiments of the present disclosure. The term “flexible” used here may indicate that the glass membrane is soft and bendable. Herein, the flexible glass membrane 100 may be applied to a glass cover of a handheld electronic device. The electronic device may include, but be not limited to, a tablet computer, a mobile phone, and the like. The electronic device may include a front cover and a back cover engaged with the front cover. The back cover may include an inner surface that cannot be seen from the outside of the electronic device, that is, the inner surface may face towards or close to the front cover.

The flexible glass membrane 100 may have a multilayer structure and may include a hot-melt adhesive layer 1, a thermoplastic polyurethane film layer 2, a base coating layer 3, a drawing-transferring layer 4, an optical coating layer 5, and an ink layer 6. The hot-melt adhesive layer 1, the thermoplastic polyurethane film layer 2, the base coating layer 3, the drawing-transferring layer 4, the optical coating layer 5, and the ink layer 6 may be successively stacked or laminated on one another.

In some embodiments, the hot-melt adhesive layer 1 may be made of xylene sol.

The flexible glass membrane 100 having the above configuration may have properties (such as optical properties, CMF processability, weather resistance, and the like) comparable to those of the PET membrane. The flexible glass membrane 100 may have a glass transition point (about 136° C.) ranged between an ambient temperature and an operative temperature of ink and drawing adhesive (the adhesive used in the drawing-transferring layer). Therefore, when a temperature of the flexible glass membrane 100 gets close to the glass transition point, the flexible glass membrane 100 may have excellent tensile properties, and may be attached to a glass cover with a large bending angle (that is to say, the glass cover has a bending portion bent at a large angle). In this way, the flexible glass membrane 100 may not be wrinkled at the bending portion of the glass cover, and may be capable of being partially or even completely attached/adhered to an edge of the glass cover. Meanwhile, texture may also be transferred to the base coating layer 3 of the flexible glass membrane 100 to form the drawing-transferring layer 4. Thus, the customer's requirements for the appearance of the texture may be satisfied.

The ink layer 6 may be attached or adhered to the inner surface of the back cover. Herein, the back cover may be a glass cover having a curved configuration with a large bending angle. In some embodiments, by attaching the ink layer 6 to the inner surface of the electronic device, it is possible not only exerts the superiority of the glass in touch and vision, but also reduces the risk of frangibility of pure glass, and the safety of the glass cover may be improved.

In some embodiments, it is also possible to arrange an anti-explosive layer 7 on a surface of the ink layer 6 that faces away from the optical coating layer 5. That is to say, the anti-explosive layer 7 and the optical coating layer 5 may be disposed at two opposite surfaces of the ink layer 6. In this case, the anti-explosive layer 7 may be attached or adhered to the inner surface of the glass cover having the curved configuration.

It should be noted that the thickness of each layer of the flexible glass membrane 100 may be not specifically limited in the present disclosure. The specific thickness of each layer may be adjusted according to the thickness and the color of the glass cover.

In some embodiments, an electronic device may be provided. The electronic device may include a front cover and a back cover. The back cover may be engaged with the front cover and may include an inner surface facing towards the front cover. The electronic device may further include the flexible glass membrane as previously described.

In some embodiments, the back cover may be a glass cover, and may have a curved configuration with a large bending angle. The ink layer 6 (in case no anti-explosive layer 7 is included in the flexible glass membrane) or the anti-explosive layer 7 (in case the flexible glass membrane includes the anti-explosive layer 7) may be attached or adhered to the inner surface of the glass cover.

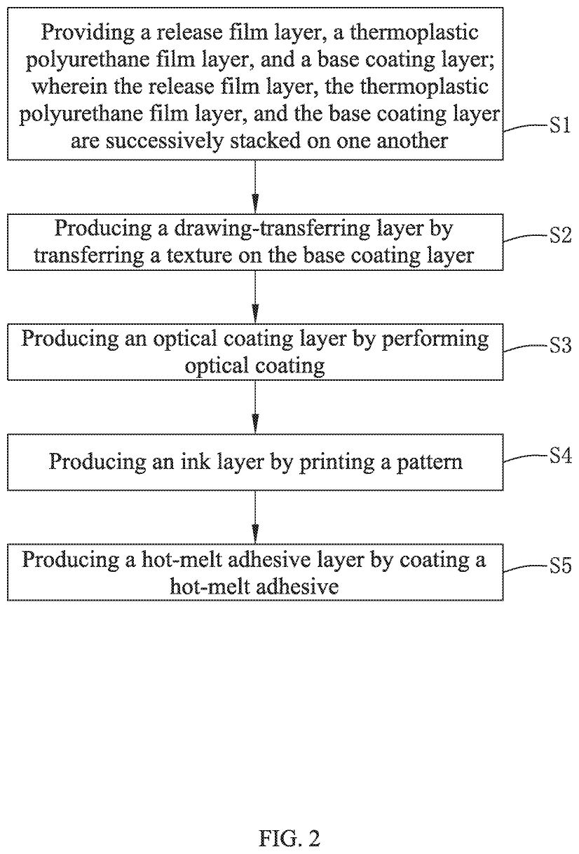

In some embodiments of the present disclosure, as shown in FIG. 2, a method for manufacturing the flexible glass membrane may be provided. The method may include operations executed by the following blocks.

At block S1: a release film layer 20, a thermoplastic polyurethane film layer 2, and a base coating layer 3 may be provided. In some embodiments, the release film layer 20, the thermoplastic polyurethane film layer 2, and the base coating layer 3 may be successively stacked on one another.

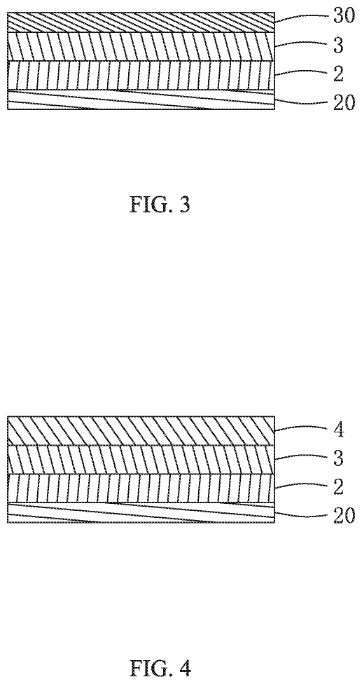

A composite structure formed by the release film layer 20, the thermoplastic polyurethane film layer 2, and the base coating layer 3 may be manufactured in advance, or may also be purchased directly. As shown in FIG. 3, generally, a protective film 30 may be further arranged on a surface of the base coating layer 3 facing away from the thermoplastic polyurethane film layer 2. That is to say, the protective film 30 and the thermoplastic polyurethane film layer 2 may be disposed at two opposite sides/surfaces of the base coating layer 3.

At block S2: a drawing-transferring layer 4 may be produced. More specifically, in some embodiments, the texture may be transferred to the surface of the base coating layer 3 facing away from the thermoplastic polyurethane film layer 2 by using a drawing-transferring machine, such that the drawing-transferring layer 4 may be formed, as shown in FIG. 4.

In some embodiments, before the drawing-transferring layer 4 is manufactured, the protective film 30 arranged on the surface of the base coating layer 3 needs to be removed or peeled off. When transferring the texture on the base coating layer 3, a UV light source may be needed for curing.

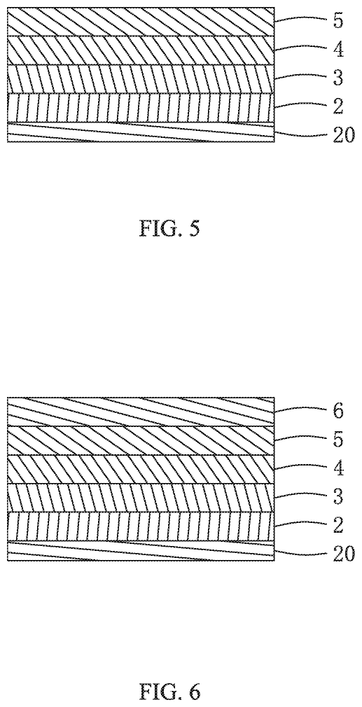

At block S3: an optical coating layer 5 may be produced. More specifically, in some embodiments, optical coating may be performed on a surface of the drawing-transferring layer 4 facing away from the base coating layer 3 by using a coating machine to form the optical coating layer 5, as shown in FIG. 5. That is to say, the base coating layer 3 and the optical coating layer 5 may be disposed on two opposite surfaces of the drawing-transferring layer 4.

At block S4, an ink layer 6 may be produced. More specifically, in some embodiments, a pattern may be printed on a surface of the optical coating layer 5 facing away from the drawing-transferring layer 4 by using a screen printing machine, in order to form the ink layer 6, as shown in FIG. 6.

At block S5: a hot-melt adhesive layer 1 may be produced. More specifically, in some embodiments, the release film layer 20 may be peeled off. In some embodiments, a hot-melt adhesive may be coated on a surface of the thermoplastic polyurethane film layer 2 facing away from the base coating layer 3 by using a drawing-transferring machine or a hot-melt adhesive coater, to form the hot-melt adhesive layer 1. In this way, the manufacturing of the flexible glass film structure 100 may be finished, and the flexible glass film structure 100 may be shown in FIG. 1.

At the block S5, generally, toluene sol may be used as the hot-melt adhesive in the industry. The toluene sol may have a fast/great volatilization speed and a fast/great condensation speed, and need to be sealed, heated, and stirred. While in some embodiments of the present disclosure, xylene sol may be used. Thus, the volatilization speed may be reduced and the product yield may be improved.

In some embodiments, the flexible glass film structure 100 may further include an anti-explosive layer 7. The method may further include a block A executed before or after the block S5. At this block A: an anti-explosive layer 7 may be produced. More specifically, in some embodiments, an anti-explosive glue may be sprayed on a surface of the ink layer 6 facing away from the optical coating layer 5 by using a spraying machine, in order to form the anti-explosive layer 7.

In some embodiments of the present disclosure, the flexible glass membrane and the method for manufacturing the flexible glass membrane may have the following effects.

1. When a temperature of the flexible glass membrane 100 gets close to the glass transition point, the flexible glass membrane 100 may have excellent tensile properties. The flexible glass membrane 100 may be attached to the glass cover with a large bending angle. The flexible glass membrane 100 may not be wrinkled at the bending portion of the glass cover and may be capable of being partially or even completely attached to the edge of the glass cover, thereby improving the safety of the glass cover.

2. The texture may also be transferred to the flexible glass membrane 100, and the customer's requirements for the appearance of the texture may be satisfied.

3. The hot-melt adhesive layer may be used, such that the glass cover may have a good sense of transparency, and a rich texture may be achieved.

4. The xylene sol may be used in the preparation of the hot-melt adhesive layer. In this way, the volatilization speed may be reduced, and the product yield may be improved.

The above may be only some embodiments of the present disclosure. It should be noted that those skilled in the art can make improvements without departing from the inventive concept of the present disclosure. All these may be covered within the protection scope of the present disclosure.

What is claimed is:

1. A flexible glass membrane, having a multilayer structure comprising a hot-melt adhesive layer, a thermoplastic polyurethane film layer, a base coating layer, a drawing-transferring layer, an optical coating layer, and an ink layer;
wherein the hot-melt adhesive layer, the thermoplastic polyurethane film layer, the base coating layer, the drawing-transferring layer, the optical coating layer, and the ink layer are successively stacked on one another.

2. The flexible glass membrane according to claim 1, wherein the flexible glass membrane is arranged on a glass cover having a curved configuration; the ink layer is attached to an inner surface of the glass cover.

3. The flexible glass membrane according to claim 1, further comprising an anti-explosive layer arranged on a surface of the ink layer that faces away from the optical coating layer;
wherein the flexible glass membrane is arranged on a glass cover having a curved configuration, and the anti-explosive layer is attached to an inner surface of the glass cover.

4. The flexible glass membrane according to claim 1, wherein the hot-melt adhesive layer is made of xylene sol.

5. The flexible glass membrane according to claim 1, wherein the flexible glass membrane has a glass transition point ranged between an ambient temperature and an operative temperature of ink and drawing adhesive.

6. An electronic device, comprising:
a front cover;
a back cover, engaged with the front cover and comprising an inner surface facing towards the front cover; and
a flexible glass membrane, comprising a hot-melt adhesive layer, a thermoplastic polyurethane film layer, a base coating layer, a drawing-transferring layer, an optical coating layer, and an ink layer; wherein the hot-melt adhesive layer, the thermoplastic polyurethane film layer, the base coating layer, the drawing-transferring layer, the optical coating layer, and the ink layer are successively stacked on one another.

7. The electronic device according to claim 6, wherein the ink layer is attached to the inner surface of the back cover.

8. The electronic device according to claim 6, further comprising an anti-explosive layer arranged on a surface of the ink layer that faces away from the optical coating layer;
wherein the anti-explosive layer is attached to the inner surface of the back cover.

9. The electronic device according to claim 6, wherein the back cover is a glass cover having a curved configuration.

10. The electronic device according to claim 6, wherein the hot-melt adhesive layer is made of xylene sol.

11. The electronic device according to claim 1, wherein the flexible glass membrane has a glass transition point ranged between an ambient temperature and an operative temperature of ink and drawing adhesive.

12. A method for manufacturing a flexible glass membrane, comprising:
providing a release film layer, a thermoplastic polyurethane film layer, and a base coating layer; wherein the release film layer, the thermoplastic polyurethane film layer, and the base coating layer are successively stacked on one another;
producing a drawing-transferring layer by transferring a texture on a surface of the base coating layer facing away from the thermoplastic polyurethane film layer;
producing an optical coating layer by performing optical coating on a surface of the drawing-transferring layer facing away from the base coating layer;
producing an ink layer by printing a pattern on a surface of the optical coating layer facing away from the drawing-transferring layer; and
producing a hot-melt adhesive layer by peeling off the release film layer, coating a hot-melt adhesive on a surface of the thermoplastic polyurethane film layer facing away from the base coating layer.

13. The method according to claim 12, further comprising:
producing an anti-explosive layer on a surface of the ink layer that faces away from the optical coating layer.

14. The method according to claim 12, wherein the hot-melt adhesive is made of xylene sol.

15. The method according to claim 12, wherein the providing the release film layer, the thermoplastic polyurethane film layer, and the base coating layer, comprises:
providing the release film layer, the thermoplastic polyurethane film layer, and the base coating layer, and a protective film; wherein the release film layer, the thermoplastic polyurethane film layer, and the base coating layer, and the protective film are successively stacked on one another.

16. The method according to claim 15, before the producing the drawing-transferring layer, the method further comprising:
peeling off the protective film.

17. The method according to claim 12, the producing the drawing-transferring layer further comprising: curing the texture by using a UV light source.
